(19) United States
(12) Patent Application Publication
(10) Pub. No.: US 2026/0206134 A1
(43) Pub. Date: Jul. 16, 2026

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventors: Woo Cheol Shim, Suwon-si (KR); Jeha Ryu, Suwon-si (KR); Hyun Kyung Park, Suwon-si (KR)

(73) Assignee: SAMSUNG ELECTRO-MECHANICS CO., LTD., Suwon-si (KR)

(21) Appl. No.: 19/340,223

(22) Filed: Sep. 25, 2025

(30) Foreign Application Priority Data
Jan. 10, 2025 (KR) 10-2025-0003977

(51) Int. Cl. H05K 1/11

(52) U.S. Cl. CPC H05K 1/11; H05K 2201/2081

(57) ABSTRACT

A printed circuit board may include an insulating layer, a pad disposed on the insulating layer, a solder resist layer disposed on the insulating layer and having an opening exposing at least a portion of the pad, and a solder bump at least partially disposed in the opening of the solder resist layer. A cross section of the solder bump cut in a direction parallel to the height direction perpendicular to a surface of the solder resist layer has a rectangular shape.

### CROSS-REFERENCE TO RELATED APPLICATION

This application claims priority to and the benefit of Korean Patent Application No. 10-2025-0003977 filed with the Korean Intellectual Property Office on Jan. 10, 2025, the entire contents of which are incorporated herein by reference.

### BACKGROUND

### 1. Technical Field

The present disclosure relates to a printed circuit board and a manufacturing method thereof.

### 2. Description of the Related Art

As electronic devices in the IT field, including mobile phones, become smaller, the size of metal posts formed in printed circuit boards on which electronic components are mounted is also decreasing.

During the manufacturing process of forming solder bumps on pad layers, an anisotropic etching of a solder resist layer may cause a difference in the thickness of the solder resist layer, which may reduce the reliability of the solder bumps disposed in openings of the solder resist layer.

### SUMMARY

Embodiments of the present disclosure attempts to provide a printed circuit board and a manufacturing method thereof capable of preventing the reliability of solder bumps from deteriorating.

However, the problem to be solved by embodiments of the present disclosure is not limited to the above-described problems and can be variously extended within the scope of the technical concept included in the present disclosure.

A printed circuit board according to an embodiment may include an insulating layer, a pad disposed on the insulating layer, a solder bump, and a solder resist layer disposed on the insulating layer and having an opening exposing at least a portion of the pad to the solder bump. The solder bump is at least partially disposed in the opening of the solder resist layer. A cross section of the solder bump may have a rectangular shape in a cross-sectional view that is cut in a direction parallel to a height direction that is perpendicular to a surface of the solder resist layer.

The solder bump may include a first portion disposed in the opening, and a second portion extending from the first portion and protruding above the solder resist layer along the height direction.

In the cross-sectional view, a first width of the first portion and a second width of the second portion may be substantially the same.

In the cross-sectional view, a third width of the opening may be substantially the same as the first width of the first portion.

The second portion may not extend onto the solder resist layer along a plane direction that is parallel to the surface of the solder resist layer.

In a plane view, that is parallel to the surface of the solder resist layer, a planar shape of the solder bump may be substantially the same as a planar shape of the opening.

The solder bump may not extend onto the solder resist layer along a plane direction that is parallel to the surface of the solder resist layer.

A manufacturing method of the printed circuit board according to an embodiment may include forming a pad disposed on an insulating layer, a forming a solder resist layer having an opening exposing at least a portion of the pad on the insulating layer, forming a solder bump in the opening of the solder resist layer, and removing a portion of the solder resist layer by plasma treatment.

The forming of the solder bump may include applying a solder material layer to fill the opening and to be disposed on the solder resist layer, and removing the solder material layer disposed on the solder resist layer.

The forming of the solder bump may include forming a mask layer on a first portion of the solder resist layer while exposing the opening on the solder resist layer, applying a solder material layer to fill the opening of the solder resist layer and to be disposed on a second portion of the solder resist layer that is not covered by the mask layer, and removing the solder material layer disposed on the solder resist layer.

In the removing of the portion of the solder resist layer by plasma treatment, the second portion of the solder bump may protrude from the solder resist layer along the height direction.

The mask layer may be a metal mask.

The mask layer may include a dry film.

The manufacturing method of the printed circuit board may further include removing the mask layer.

The removing of the mask layer may be performed together with the removing the solder material layer.

According to embodiments, a printed circuit board and a manufacturing method thereof capable of preventing the reliability of solder bumps from deteriorating may be provided.

However, it is obvious that the effects of the embodiments are not limited to the above-described effects, and may be variously extended without departing from the concept and scope of the present disclosure.

### BRIEF DESCRIPTION OF THE DRAWINGS

FIG. 1 is a plane view illustrating a portion of a printed circuit board according to an embodiment.

FIG. 2 is a cross-sectional view along the line I-I′ of FIG. 1.

FIG. 3 to FIG. 7 are cross-sectional views illustrating a manufacturing method of a printed circuit board according to an embodiment.

FIG. 8 and FIG. 9 are cross-sectional views illustrating a manufacturing method of a printed circuit board according to an embodiment.

### DETAILED DESCRIPTION

Hereinafter, various embodiments of the present disclosure will be described in detail so that a person of ordinary skill in the technical field to which the present disclosure belongs can easily implement it with reference to the accompanying drawings. The present disclosure may be implemented in various different forms and is not limited to the embodiments described herein.

In order to clearly describe the present disclosure, parts unrelated to the description are omitted in the drawings, and the same reference numerals are designated to the same or similar elements throughout the specification.

The accompanying drawings are provided only in order to allow embodiments disclosed in the present specification to be easily understood and are not to be interpreted as limiting the technical concept disclosed in the present specification, and it is to be understood that the present disclosure includes all modifications, equivalents, and substitutions without departing from the scope and concept of the present disclosure.

In addition, the size and thickness of each element illustrated in the drawings are arbitrarily illustrated for convenience of explanation, so this disclosure is not necessarily limited to the drawings. In the drawings, thicknesses are enlarged to clearly illustrate layers and regions. Further, in the drawings, for convenience of explanation, the thickness of some layers and areas are exaggerated.

Furthermore, it will be understood that when an element such as a layer, film, region, or substrate is referred to as being “on” another element, it can be directly on the other element or intervening elements may also be present. On the contrary, when an element is referred to as being “directly on” another element, there are no intervening elements present. Furthermore, in the specification, the word “on” or “above” means positioned on or below the object portion and does not necessarily mean positioned on the upper side of the object portion based on a gravitational direction.

Furthermore, throughout the specification, unless explicitly described to the contrary, the word “comprise” and variations such as “comprises” or “comprising” will be understood to imply the inclusion of other elements but not the exclusion of any other elements.

Throughout the specification, the term “in a plane view” refers to viewing the target portion from above, while the term “in a cross-sectional view” refers to viewing the target portion from the side after making a vertical section.

Furthermore, throughout the specification, “connected” means that two or more elements are not only directly connected, but two or more elements may be connected indirectly through other elements, physically connected as well as being electrically connected, or it may be referred to by different names depending on the location or function but may mean integral.

Hereinafter, various embodiments and modified embodiments will be described in detail with reference to the drawings.

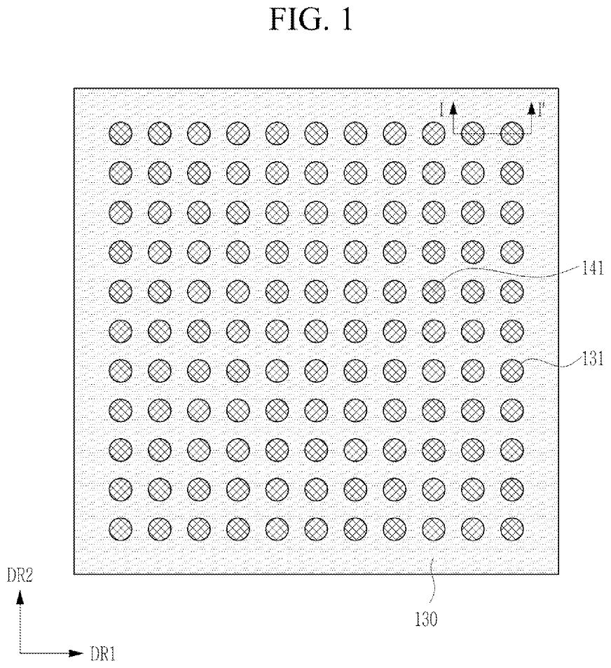

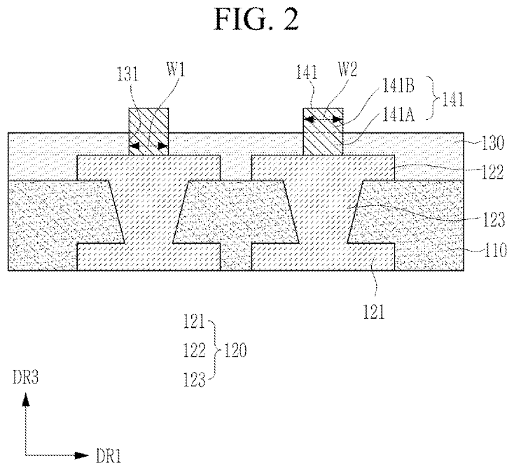

A printed circuit board according to an embodiment will be described with reference FIG. 1 and FIG. 2. FIG. 1 is a plan view illustrating a portion of a printed circuit board according to an embodiment, and FIG. 2 is a cross-sectional view along the line I-I′ of FIG. 1.

Referring to FIG. 1 and FIG. 2, the printed circuit board according to an embodiment may include an insulating layer 110, wiring layers 120 that are at least partially embedded in the insulating layer 110, a solder resist layer 130 disposed on the insulating layer 110 and having a plurality of openings 131 exposing pads 122, and a plurality of solder bumps 141 disposed in the plurality of the openings 131 of solder resist layer 130.

The insulating layer 110 may include a thermosetting resin such as an epoxy resin, a thermoplastic resin such as polyimide, or a resin in which a reinforcing material such as a glass fiber or an inorganic filler is impregnated, for example, a prepreg, but embodiments are not limited thereto. The insulating layer 110 may be a plurality of layers.

The wiring layers 120 may include wiring layers 121 embedded in the insulating layer 110, pads 122 disposed on the insulating layer 110, and vias 123 connecting the wiring layers 121 and the pads 122.

The pads 122 may electrically connect an external device such as a semiconductor chip to the printed circuit board.

The wiring layers 120 may include a conductive metal, for example, copper, but embodiment is not limited thereto.

The solder resist layer 130 may cover the insulating layer 110 and the wiring layers 120, and the openings 131 of the solder resist layer 130 may expose at least a portion of at least one of the pads 122, respectively.

The solder resist layer 130 may be a photoresist layer, but embodiment is not limited thereto.

At least a portion of each of the solder bumps 141 may be disposed in one of the openings 131 of the solder resist layer 130.

In a cross-sectional view cut along a direction parallel to a third direction DR3 that is a height direction perpendicular to a first and a second directions DR1 and DR2 parallel to a surface of the solder resist layer 130, each cross section of the solder bumps 141 may have a substantially rectangular shape.

Each of the solder bumps 141 may include a first portion 141A disposed in the openings 131 of the solder resist layer 130, and a second portion 141B extending from the first portion 141A and protruding above the solder resist layer 130 along the third direction DR3 that is the height direction.

In the cross-sectional view, the first portion 141A of each of the solder bumps 141 may have a first width W1, and the second portion 141B may have a second width W2. The first width W1 and the second width W2 may be substantially the same. The second portion 141B of each of the solder bumps 141 may have a substantially constant second width W2 up to the end.

In one embodiment, in the cross-sectional view cut along a direction parallel to the third direction DR3, each of the solder bumps 141 may have a substantially trapezoidal shape.

For example, the first width W1 of the first portion 141A of each of the solder bumps 141 and the second width W2 of the second portion 141B of each of the solder bumps 141 may gradually increase along the third direction DR3. However, the embodiment is not limited thereto.

Each of the solder bumps 141 may have a width substantially equal to the third width W3 of each of the openings 131 of the solder resist layer 130, and the first portion 141A of each of the solder bumps 141 may fill each of the openings 131. W1, W2, and W3 may be measured using a electron microscope. Other methods and/or tools appreciated by one of ordinary skill in the art, even if not described in the present disclosure, may also be used.

As used herein, the expression “substantially the same” may refer to having the same width or dimensions (in the context of a planar shape) relative to the width or dimensions, respectively, compared therewith, as will be appreciated by those of skill in the art, and allows for approximations, inaccuracies and limits of measurement under the relevant circumstances. In one or more aspects, the terms “substantially,” and “approximately” may provide an industry-accepted tolerance for their corresponding terms and/or relativity between items, such as a tolerance of ±1%, ±5%, or ±10% of the actual value stated, and other suitable tolerances.

The second portion 141B of each of the solder bumps 141 may not extend onto the solder resist layer 130 along a plane direction parallel to a surface of the insulating layer 110.

In a plane view of the printed circuit board viewed from above, a planar shape of each of the solder bumps 141 may be substantially the same as a planar shape of each of the openings 131 of the solder resist layer 130.

In FIG. 1, the planar shape of each of the openings 131 of the solder resist layer 130 and the planar shape of each of the solder bumps 141 are substantially circular, but the embodiment is not limited thereto, and the planar shape of each of the solder bumps 141 and the planar shape of each of the openings 131 of the solder resist layer 130 can be variously modified under the conditions of having substantially the same planar shape.

In an embodiment, each of the solder bumps 141 may include a first portion 141A disposed in the openings 131 of the solder resist layer 130, and a second portion 141B extending from the first portion 141A and protruding above the solder resist layer 130 along the third direction DR3 that is the height direction, and the first portion 141A and the second portion 141B may have substantially the same width. In addition, each of the solder bumps 141 may have a substantially rectangular shape in a cross-sectional view cut in a direction perpendicular to the first and second directions DR1 and DR2 parallel to the surface of the insulating layer 110. Furthermore, the first portion 141A of each of the solder bumps 141 may have a shape filling each of the openings 131 of the solder resist layer 130, the second portion 141B of each of the solder bumps 141 may not extend onto the solder resist layer 130 along a plane direction parallel to the surface of the insulating layer 110, and the thicknesses of the second portions 141B of each of the solder bumps 141 protruding above the solder resist layer 130 along the third direction DR3 that is the height direction may be substantially the same. Therefore, the plane area of each of the openings 131 of the solder resist layer 130 in which the solder bumps 141 connected to the pads 122 are disposed is not larger than the plane area of each of the solder bumps 141, so the pads 122 may not be unnecessarily exposed through the openings 131 of the solder resist layer 130. In addition, not only the first portion 141A of the solder bumps 141 but also the second portion 141B of the solder bumps 141 may be aligned with the openings 131 of the solder resist layer 130 along the height direction, so that no misalignment occurs between the solder bumps 141 and the pads 122. Furthermore, the second portion 141B of each of the solder bumps 141 protruding above the solder resist layer 130 may have a uniform thickness, thereby reducing a thickness deviation of the solder bumps and preventing a decrease in reliability of the solder bumps.

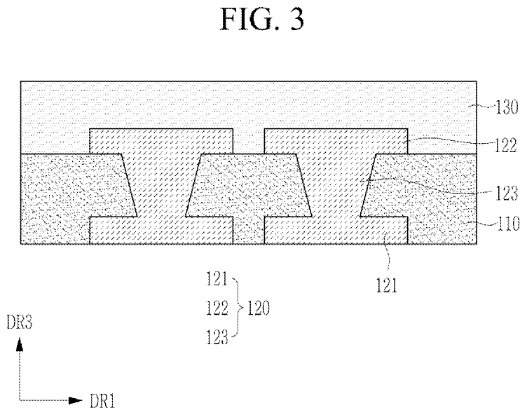

A manufacturing method of the printed circuit board according to an embodiment will be described with reference FIG. 3 to FIG. 7, together with FIG. 1 and FIG. 2. FIG. 3 to FIG. 7 are cross-sectional views illustrating a manufacturing method of a printed circuit board according to an embodiment.

Referring to FIG. 3, wiring layers 121 may be formed, the insulating layer 110 may be formed on the wiring layers 121 such that the wiring layers 121 are embedded in the insulating layer 110, via holes may be formed in the insulating layer 110, vias 123 in the via hole and pads 122 connected to the vias 123 may be formed together, and then the solder resist layer 130 may be stacked on the insulating layer 110 and the pads 122.

The thickness of the stacked solder resist layer 130 may be substantially equal to or greater than the sum of the thickness of pads 122 and the thickness of solder bumps 141.

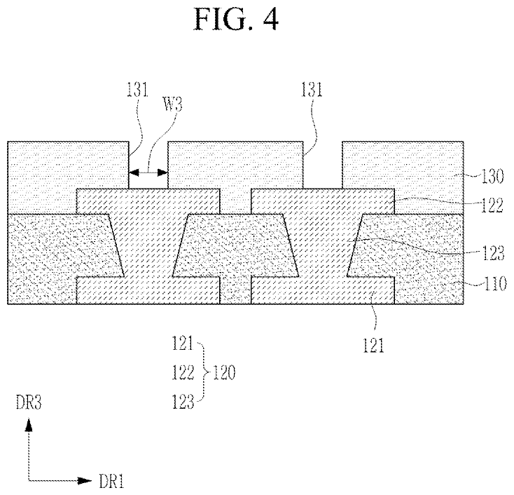

Referring to FIG. 4, the stacked solder resist layer 130 may be exposed and developed to form the openings 131 exposing at least a portion of each of the pads 122, respectively.

In the cross-sectional view cut along the third direction DR3 that is the height direction, each of the openings 131 may have a third width W3, and, as described with reference to FIG. 1 and FIG. 2, the third width W3 of each of the openings 131 may be substantially the same as the widths W1 and W2 of each of the solder bumps 141.

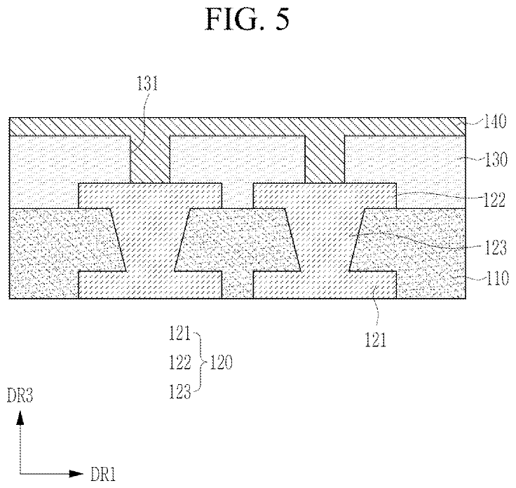

Referring to FIG. 5, a solder material layer 140 may be applied so as to fill the openings 131 of the solder resist layer 130 and to be disposed on the solder resist layer 130. The solder material layer 140 may be a liquid. The solder material layer 140 is applied to overflow onto the solder resist layer 130 after filling the openings 131, so that the upper surface of the solder material layer 140 can be substantially flat.

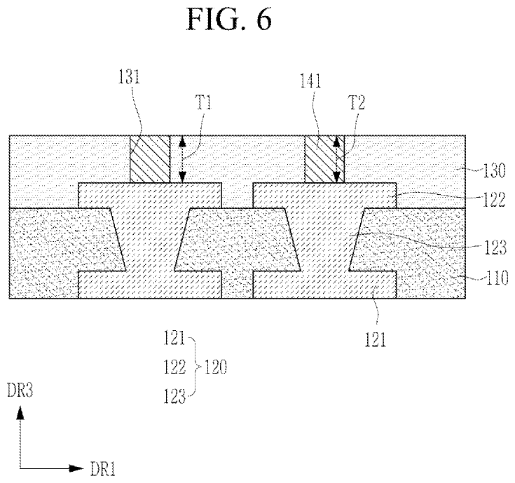

Referring to FIG. 6, the solder material layer 140 disposed on the solder resist layer 130 may be removed by a method such as wet etching to form solder bumps 141 disposed in the openings 131 of the solder resist layer 130. A first thickness T1 of the solder resist layer 130 disposed on the pads 122 and a second thickness T2 of each of the solder bumps 141 may be substantially the same.

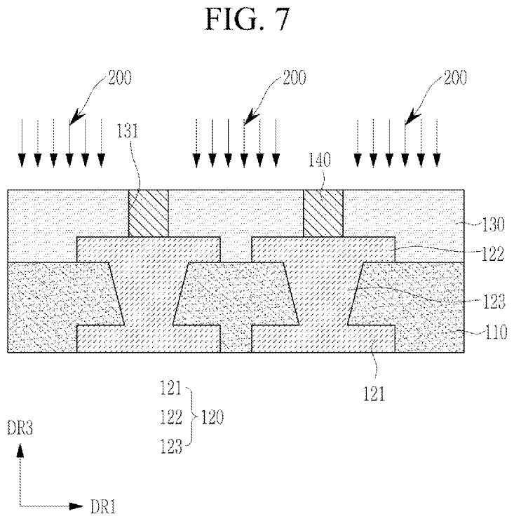

Referring to FIG. 7, a portion of the solder resist layer 130 may be etched by plasma treatment 200. By removing the portion of the solder resist layer 130, the thickness of the solder resist layer 130 may be reduced to expose the second portion 141B of each of the solder bumps 141.

Through this, as illustrated in FIG. 2, the solder bumps 141 including the first portion 141A disposed in the openings 131 of the solder resist layer 130 and the second portion 141B extending from the first portion 141A and protruding above the solder resist layer 130 along the third direction DR3 that is height direction, respectively may be formed.

According to an embodiment, the solder bumps 141 may be formed by removing a portion of the solder resist layer 130 through the plasma treatment 200 after forming the openings 131 of the solder resist layer 130, applying the solder material layer 140 to fill the openings 131 of the solder resist layer 130 and to be disposed on the solder resist layer 130, and removing a portion of the solder material layer 140 disposed on the solder resist layer 130 by the method such as wet etching.

When wet etching is used to remove the portion of the solder resist layer during the manufacturing process, etching solution may be sprayed unevenly depending on the location, and thus the degree of etching of the solder resist layer may not be uniform. However, according to an embodiment, after exposing and developing the solder resist layer, the portion of the solder resist layer 130 is etched and removed through plasma treatment 200, so that the solder resist layer can be removed uniformly, and the thickness of the second portions 141B of the solder bumps 141 protruding above the solder resist layer 130 may be uniform. Accordingly, it is possible to reduce the thickness deviation of the second portions 141B of the solder bumps 141 that may occur due to the thickness deviation of the solder resist layer 130 depending on the location, thereby preventing the reliability of the solder bump from deteriorating.

Various features of the printed circuit board according to the above-described embodiment are applicable to the manufacturing method of the printed circuit board according to an embodiment.

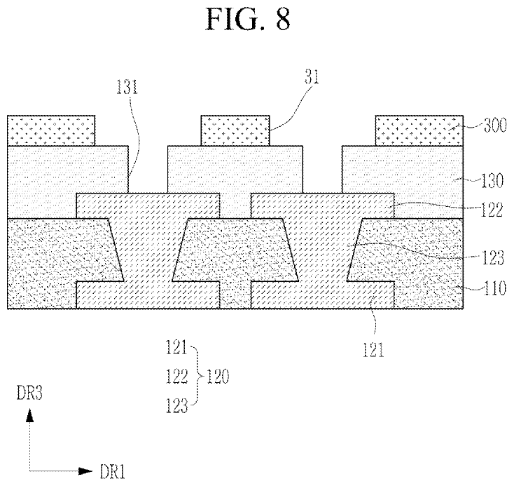

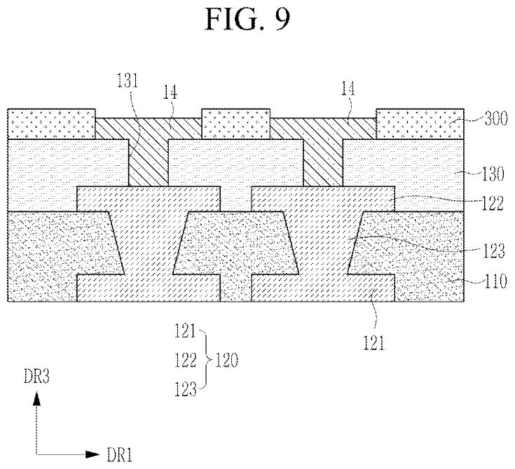

A manufacturing method of the printed circuit board according to an embodiment will be described with reference FIG. 8 to FIG. 9, together with FIG. 1 to FIG. 4.

As described with reference to FIG. 3 and FIG. 4, the wiring layers 120 may be formed to be at least partially embedded in the insulating layer 110. The solder resist layer 130 may be stacked on the insulating layer 110 and the pads 122, and the stacked solder resist layer 130 may be exposed and developed to form the openings 131 exposing at least a portion of each of the pads 122.

As illustrated in FIG. 8, a mask layer 300 having openings 31 having a large diameter sufficiently exposing the openings 131 may be formed on the solder resist layer 130. The mask layer 300 may be a metal mask layer, and may include a dry film. However, embodiment is not limited thereto, and various mask layers may be used.

Referring to FIG. 9, the solder material layer 140 may be applied into the openings 31 of the mask layer 300. The solder material layer 140 may fill the openings 31 of the mask layer 300. Therefore, the solder material layer 140 may fill the openings 131 of the solder resist layer 130 and may be disposed on the solder resist layer 130 not covered by the mask layer 300.

According to the present embodiment, since the solder material layer 140 is not applied to a portion covered by the mask layer 300, a coating amount of the solder material layer 140 may be reduced, thereby reducing a manufacturing cost.

Next, the solder bumps 141 disposed in the openings 131 of the solder resist layer 130 may be formed by removing the mask layer 300 and removing the solder material layer 140 disposed on the solder resist layer 130 by a method such as wet etching. The mask layer 300 may be removed together with the solder material layer 140.

Next, the second portion 141B of each of the solder bumps 141 may be exposed by etching a portion of the solder resist layer 130 through the plasma treatment 200 to reduce the thickness of the solder resist layer 130.

Through this, as illustrated in FIG. 2, the solder bumps 141 including the first portion 141A disposed in the openings 131 of the solder resist layer 130 and the second portion 141B extending from the first portion 141A and protruding above the solder resist layer 130 along the third direction DR3 that is height direction, respectively may be formed.

According to an embodiment, the solder bumps 141 may be formed by etching the portion of the solder resist layer 130 through the plasma treatment 200 after forming the openings 131 of the solder resist layer 130, forming the mask layer 300 having the openings 31 with a large diameter sufficiently exposing the openings 131, applying the solder material layer 140 to fill the openings 131 of the solder resist layer 130 and to be disposed on the solder resist layer 130 not covered by the mask layer 300, and removing the solder material layer 140 disposed on the solder resist layer 130 by the method such as wet etching.

According to an embodiment, after exposing and developing the solder resist layer, the portion of the solder resist layer 130 may be etched and removed through plasma treatment 200, so that the solder resist layer can be uniformly removed and the second portions 141B of the solder bumps 141 can be uniformly protruded from the solder resist layer 130.

Accordingly, the thickness deviation of the second portions 141B of the solder bumps 141 that may occur due to the thickness deviation of the solder resist layer 130 may be reduced, thereby preventing a decrease in reliability of the solder bump.

Various features of the printed circuit board and the manufacturing method of the printed circuit board according to the above-described embodiment are applicable to the manufacturing method of the printed circuit board according to the present embodiment.

While embodiments of the present disclosure have been described above, the present disclosure is not limited thereto, and it is possible to perform various modifications within the scope of the claims, the detailed description, and the accompanying drawings, and it is natural that these modifications also fall within the scope of the present disclosure.

What is claimed is:

1. A printed circuit board comprising;
an insulating layer,
a pad disposed on the insulating layer,
a solder bump, and
a solder resist layer disposed on the insulating layer and having an opening exposing at least a portion of the pad to the solder bump,
wherein the solder bump is at least partially disposed in the opening of the solder resist layer, and
wherein a cross section of the solder bump has a rectangular shape in a cross-sectional view that is cut in a direction parallel to a height direction that is perpendicular to a surface of the solder resist layer.

2. The printed circuit board of claim 1, wherein:
the solder bump comprises a first portion disposed in the opening, and a second portion extending from the first portion and protruding above the solder resist layer along the height direction.

3. The printed circuit board of claim 2, wherein:
in the cross-sectional view, a first width of the first portion and a second width of the second portion are substantially the same.

4. The printed circuit board of claim 3, wherein:
in the cross-sectional view, a third width of the opening is substantially the same as the first width of the first portion.

5. The printed circuit board of claim 4, wherein:
the second portion does not extend onto the solder resist layer along a plane direction that is parallel to the surface of the solder resist layer.

6. The printed circuit board of claim 5, wherein:
in a plane view, parallel to the surface of the solder resist layer, a planar shape of the solder bump is substantially the same as a planar shape of the opening.

7. The printed circuit board of claim 1, wherein:
in a plane view, parallel to the surface of the solder resist layer, a planar shape of the solder bump is substantially the same as a planar shape of the opening.

8. The printed circuit board of claim 7, wherein:
the solder bump does not extend onto the solder resist layer along a plane direction that is parallel to the surface of the solder resist layer.

9. A manufacturing method of a printed circuit board, comprising:
forming a pad disposed on an insulating layer,
forming a solder resist layer having an opening exposing at least a portion of the pad on the insulating layer,
forming a solder bump in the opening of the solder resist layer, and
removing a portion of the solder resist layer by plasma treatment.

10. The manufacturing method of claim 9, wherein:
the forming of the solder bump comprises
applying a solder material layer to fill the opening and to be disposed on the solder resist layer, and
removing the solder material layer disposed on the solder resist layer.

11. The manufacturing method of claim 10, wherein:
the solder bump comprises a first portion disposed in the opening, and a second portion extending from the first portion and protruding above the solder resist layer along a height direction that is perpendicular to a surface of the solder resist layer, and
in the removing of the portion of the solder resist layer by plasma treatment, the second portion of the solder bump protrudes from the solder resist layer along the height direction.

12. The manufacturing method of claim 11, wherein:
in a cross-sectional view cut in a direction parallel to the height direction, a first width of the first portion and a second width of the second portion are substantially the same.

13. The manufacturing method of claim 12, wherein:
in the cross-sectional view, a third width of the opening is substantially the same as the first width of the first portion.

14. The manufacturing method of claim 11, wherein:
in a cross-sectional view cut in a direction parallel to the height direction, the solder bump has a rectangular shape.

15. The manufacturing method of claim 9, wherein:
the forming of the solder bump comprises forming a mask layer on a first portion of the solder resist layer while exposing the opening on the solder resist layer,
applying a solder material layer to fill the opening of the solder resist layer and to be disposed on a second portion of the solder resist layer that is not covered by the mask layer, and
removing the solder material layer disposed on the solder resist layer.

16. The manufacturing method of claim 15, wherein:
the mask layer is a metal mask.

17. The manufacturing method of claim 15, wherein:
the mask layer comprises a dry film.

18. The manufacturing method of claim 15, wherein:
the solder bump comprises a first portion disposed in the opening, and a second portion extending from the first portion and protruding above the solder resist layer along a height direction that is perpendicular to a surface of the solder resist layer, and
in the removing of the portion of the solder resist layer by plasma treatment, the second portion of the solder bump protrudes from the solder resist layer along the height direction.

19. The manufacturing method of claim 15, further comprising:
removing the mask layer.

20. The manufacturing method of claim 19, wherein:
the removing of the mask layer is performed together with the removing of the solder material layer.
